(19) United States
(12) Patent Application Publication
(10) Pub. No.: US 2024/0322327 A1
(43) Pub. Date: Sep. 26, 2024

(54) BATTERY MODULE

(71) Applicant: EVE POWER CO., LTD., Jingmen (CN)

(72) Inventors: Chaoju REN, Jingmen (CN); Jungao LU, Jingmen (CN); Guojiang ZHANG, Jingmen (CN); Yuhong XU, Jingmen (CN); Jibing JIANG, Jingmen (CN)

(21) Appl. No.: 18/284,370

(22) PCT Filed: Dec. 1, 2022
(86) PCT No.: PCT/CN2022/135749

§ 371 Date: Sep. 27, 2023

(30) Foreign Application Priority Data
Nov. 7, 2022 (CN) 202222956571.5

(51) Int. Cl. H01M 50/242; H01M 50/213; H01M 50/262; H01M 50/284; H01M 50/289; H01M 50/505; H01M 50/514; H01M 50/519; H05K 1/02

(52) U.S. Cl. CPC H01M 50/242; H01M 50/213; H01M 50/262; H01M 50/284; H01M 50/289; H01M 50/505; H01M 50/514; H01M 50/519; H05K 1/0281

(57) ABSTRACT

The present application discloses a battery module, including: a mounting bracket including a first mounting surface and a second mounting surface disposed opposite to each other, where the first mounting surface is provided with a plurality of fixing plates; a busbar assembly detachably connected to the mounting bracket and disposed on the second mounting surface; a plurality of cells arranged on the first mounting surface and connected to the bus bar assembly; an FPC board assembly including a plurality of FPC boards and a plurality of connectors, where the FPC boards are vertically disposed on the first mounting surface, a connection end of each of the FPC boards is fixedly connected to respective one of the connectors and riveted to respective one of the fixing boards.

This application claims priority to Chinese Patent Application No. 202222956571.5, filed with the Chinese Patent Office on Nov. 7, 2022, the disclosure of which is incorporated herein by reference in its entirety.

### TECHNICAL FIELD

The present application relates to the field of battery technologies, and for example to a battery module.

### BACKGROUND

The smallest unit of a power battery is a cell. One power battery includes hundreds of individual cells, where a group of cells may form a battery module, and a plurality of battery modules may form the power battery. In order to fix position of the cells, the battery module is generally provided with a mounting bracket, and assembling of the battery module includes fixing structural members such as cells, an Flexible Printed Circuit (FPC) board, an acquisition wiring harness, a connector, and a busbar to the mounting bracket. If these structural members are all separately fed, it will result in an increase in the types of materials, an increase in the difficulty of material management and control, and an impact on assembly efficiency and product quality at an assembling station of the battery module.

In addition, the connector is generally installed in a manner of snap connection for the battery module in the related art and fixed to the mounting bracket by the snap. Since the snap is easily loosened and vibration of the battery module in use may cause the connector to shake, resulting in a poor acquisition contact and affecting reliability of the battery module.

### SUMMARY

The present application provides a battery module capable of realizing integrated feeding at a cell assembling station, and reliable riveting connection between a connector and a mounting bracket, thereby improving assembly efficiency and assembly quality and ensuring work reliability.

The present application provides a battery module, including:
a mounting bracket including a first mounting surface and a second mounting surface disposed opposite to each other, where the first mounting surface is provided with a plurality of fixing plates;
a busbar assembly detachably connected to the mounting bracket and disposed on the second mounting surface;
a plurality of cells arranged on the first mounting surface and connected to the busbar assembly; and
an FPC board assembly including a plurality of FPC boards and a plurality of connectors, where the FPC boards are vertically disposed on the first mounting surface, and a connection end of each of the FPC boards is fixedly connected to respective one of the connectors and riveted to respective one of the fixing plates.

In an embodiment, the FPC board assembly further includes a reinforcing plate connected to a side of the connection end away from the connector and riveted to the fixing plate.

In an embodiment, the fixing plate is provided with a plurality of riveting posts, the reinforcing plate and the connection end both are provided with a plurality of positioning holes through which the riveting posts can pass and be riveted to the reinforcing plate and the connection end.

In an embodiment, the mounting bracket further includes a plurality of reinforcing ribs each connected to a side of the fixing plate away from the connection end.

In an embodiment, the busbar assembly includes a negative output busbar, where the negative output busbar includes a bent output end parallel to an axial direction of the cell and configured to connect an adjacent battery module.

In an embodiment, the bent output end is attached to the mounting bracket and provided with a connection bolt, an axial direction of the connection bolt is perpendicular to a side surface of the mounting bracket, and the connection bolt is configured to connect the adjacent battery module and screwed to a mounting hole of the bent output end.

In an embodiment, the plurality of FPC boards include a first FPC board embedded among the plurality of cells and a second FPC board disposed around an outer periphery of the cells.

In an embodiment, the first FPC board includes a bent extension portion capable of attaching a side of the plurality of cells.

In an embodiment, the mounting bracket includes a plurality of first limiting members protruded on the first mounting surface and configured to snap-fit the cells.

In an embodiment, the mounting bracket includes a plurality of second limiting members protruded on the second mounting surface and configured to snap-fit the busbar assembly.

### Beneficial Effects of the Present Application

According to the battery module provided in the present application, the FPC boards are vertically arranged on the first mounting surface, and thus the FPC boards do not affect the assembling of the cells, so that the busbar assembly, the mounting bracket, and the FPC board assembly can be pre-assembled in advance. The busbar assembly, the mounting bracket, and the FPC board assembly are assembled in a preceding working procedure, so that the integrated feeding is realized, the types of the materials are reduced, difficulty of the material management and control is reduced, the occupation of equipment and a field is reduced, and the assembly efficiency and the product quality are improved. At the same time, the connection end of the FPC board is fixedly connected to the connector and riveted to the fixing plate, so that the installation of the connector is realized, the manufacturing process is simple, the processing cost is low, the fixing is reliable, the looseness does not occur, even the vibration of the battery module in use is difficult to cause the vibration of the connector, the poor acquisition contact is avoided, and the working reliability of the battery module is ensured.

### BRIEF DESCRIPTION OF THE DRAWINGS

FIG. 1 is a first schematic structural diagram of a battery module according to some embodiments of the present application.

FIG. 2 is a second schematic structural diagram of a battery module according to some embodiments of the present application.

FIG. 3 is a partially enlarged view of a portion A of the battery module in FIG. 1.

FIG. 4 is a partially enlarged view of a portion B of the battery module in FIG. 2.

FIG. 5 is a schematic structural diagram of a negative output busbar according to some embodiments of the present application.

FIG. 6 is a first schematic structural diagram of a mounting bracket according to some embodiments of the present application.

FIG. 7 is a partially enlarged view of a portion C of the battery module in FIG. 6.

FIG. 8 is a second schematic structural diagram of a mounting bracket according to some embodiments of the present application.

FIG. 9 is a partially enlarged view of a portion D of the battery module in FIG. 8.

In FIGS:

1. Mounting bracket; 11. First mounting surface; 12. Second mounting surface; 13. Fixing plate; 131. Riveting post; 14. Reinforcing rib; 15. First limiting member; 16. Second limiting member; 2. Busbar assembly; 21. Negative output busbar; 211. Bent output end; 2111. Mounting hole; 212. Connection bolt; 3. Cell; 4. FPC board assembly; 40. Positioning hole; 41. FPC board; 411. Connection end; 412. First FPC board; 413. Second FPC board; 42. Connector; 43. Reinforcing plate.

### DETAILED DESCRIPTION

In description of the present application, it should be noted that the terms “interconnection”, “connection” and “fixing” should be understood in a broad sense, unless otherwise clearly specified. For example, “fixing” can be a fixed connection, a detachable connection, or integrated connection. It can be a mechanical connection or an electrical connection. It can be directly connected or indirectly connected through an intermediary. It can also be the connection between two elements or the interaction between two elements. Those ordinary skilled in the art can understand the meanings of the above terms in the present application according to actual situations.

In the present application, it should be noted that unless otherwise clearly specified, a first feature “on” or “under” a second feature may mean that the first feature directly contacts the second feature, or that the first feature contacts the second feature via an additional feature there between instead of directly contacting the second feature. Moreover, the first feature “on”, “above”, and “over” the second feature may mean that the first feature is right over or obliquely upward over the second feature or mean that the first feature has a horizontal height higher than that of the second feature. The first feature “under”, “below”, and “beneath” the second feature may mean that the first feature is right beneath or obliquely downward beneath the second feature or mean that horizontal height of the first feature is lower than that of the second feature.

In the description of the embodiments, orientations or position relationships indicated by the terms “upper”, “lower”, “left”, “right” are based on orientations or position relationships illustrated in the drawings. The terms are used to facilitate the description and simplify the operations, rather than indicate or imply that the devices or elements referred to herein are required to have specific orientations or be constructed or operate in the specific orientations. In addition, the terms “first” and “second” are used solely for the purpose of distinguishing elements in terms of description of the elements and not in a particular sense.

The smallest unit of a power battery is a cell. The power battery includes hundreds of individual cells, where a group of cells may form a battery module, and a plurality of battery modules may form the power battery. The assembling of the battery module includes fixing the structural members such as the cells, the FPC board, the acquisition wiring harness, the connector, and the busbar to the mounting bracket. If these structural members are all separately fed, it will result in the increase in the types of materials, the increase in the difficulty of material management and control, and the impact on the assembly efficiency and the product quality at the assembling station of the battery module. If the structural members such as the FPC board, the connector, and the busbar, and the mounting bracket are integrally assembled and fed together in a preceding working procedure, the FPC board and the busbar occupy a larger space area, and is easily interfered with the fixing mounting of the cells. It is also necessary to disassemble the FPC board, and then assemble the FPC board to the mounting bracket after completing installation of the cells, thereby adding additional process and seriously affecting the mounting efficiency.

In addition, the connector is generally installed in a manner of snap connection for the battery module in the related art and fixed to the mounting bracket by the snap. Since the snap is easily loosened and vibration of the battery module in use may cause the connector to shake, resulting in the poor acquisition contact and affecting reliability of the battery module. In order to solve the above technical problems, embodiments of the present application provide a battery module.

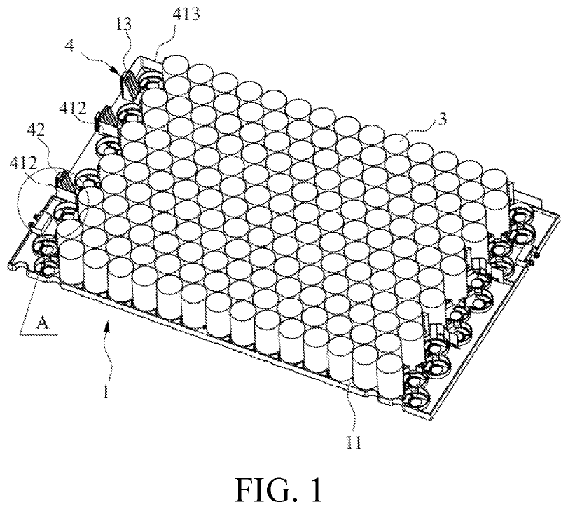

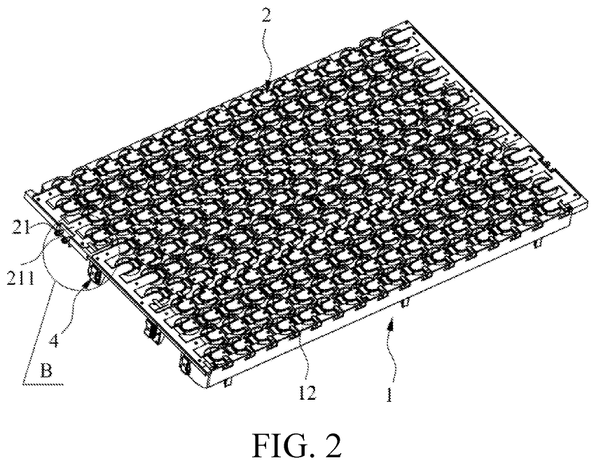

As shown in FIGS. 1 to 9, embodiments of the present application provide a battery module, including a mounting bracket 1, a bus bar assembly 2, a plurality of cells 3, and an FPC board assembly 4. The mounting bracket 1 includes a first mounting surface 11 and a second mounting surface 12 disposed opposite to each other 1, where the first mounting surface 11 is provided with a plurality of fixing plates 13. The busbar assembly 2 is detachably connected to the mounting bracket 1 and disposed on the second mounting surface 12. The plurality of cells 3 are arranged on the first mounting surface 11 and connected to the bus bar assembly 2. The FPC board assembly 4 includes a plurality of FPC boards 41 and a plurality of connectors 42. The FPC boards 41 are vertically arranged on the first mounting surface 11, and thus the FPC boards 41 do not affect the assembling of the cells 3, so that the busbar assembly 2, the mounting bracket 1, and the FPC board assembly 4 can be pre-assembled in advance. The busbar assembly 2, the mounting bracket 1, and the FPC board assembly 4 are assembled in the preceding working procedure, so that the integrated feeding is realized at the assembling station of the cells 3, the types of the materials are reduced, difficulty of the material management and control is reduced, the occupation of equipment and a field is reduced, and the assembly efficiency and the product quality are improved.

A connection end 411 of each of the FPC boards 41 is fixedly connected to respective one of the connectors 42 and riveted to respective one of the fixing boards 13, so that installation of the connector 42 is implemented. Alternatively, the mounting bracket 1 is manufactured from a plastic material, and is easily riveted to the connection end 411 by a hot riveting connection. The manufacturing process is simple, the manufacturing cost is low, the fixing is reliable, and no looseness is generated. The vibration of the battery module in use makes it difficult to cause the vibration of the connector 42, thereby avoiding poor acquisition contact and ensuring the working reliability of the battery module.

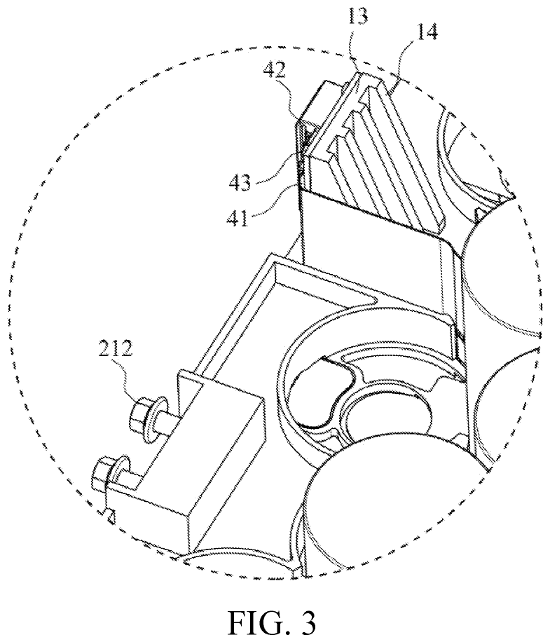

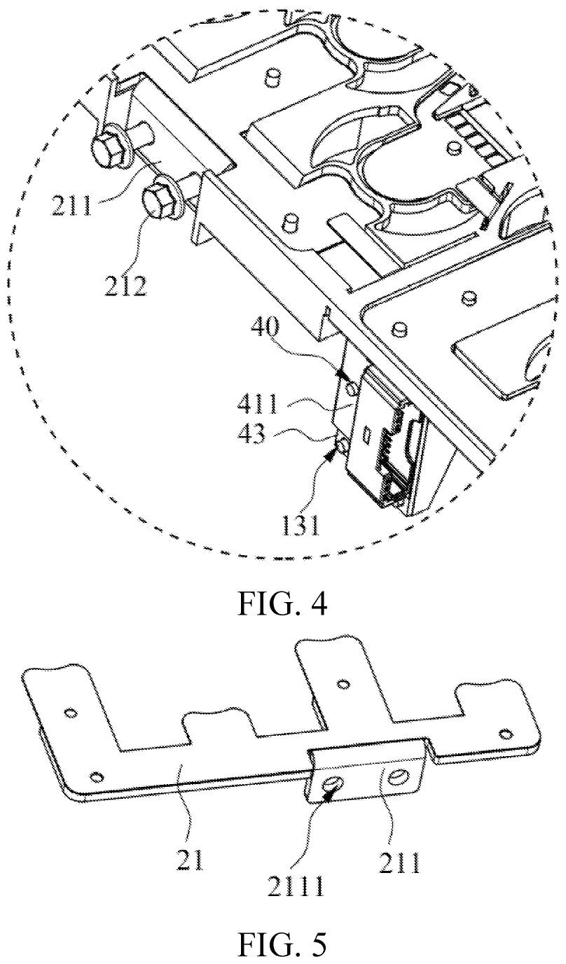

In an embodiment, the FPC board assembly further includes a plurality of reinforcing plates 43. As shown in FIGS. 3 and 4, each of the reinforcing plates 43 is connected to a side of respective one of the connection ends 411 away from respective one of the connectors 42 and riveted to respective one of the fixing plates 13. The reinforcing plate 43 is capable of increasing the strength of the connection end 411 and fixing the connector 42 more firmly. Illustratively, the fixing plate 13 is provided with a plurality of riveting posts 131, the reinforcing plate 43 and the connection end 411 both are provided with a plurality of positioning holes 40 through which the riveting posts 131 can pass and be riveted to the reinforcing plate 43 and the connection end 411.

In an embodiment, the mounting bracket 1 further includes a plurality of reinforcing ribs 14. As shown in FIG. 3, each of the reinforcing ribs 14 is connected to a side of respective one of the fixing plates 13 away from respective one of the connection ends 411. The mounting bracket 1 of the present embodiment is provided with four reinforcing ribs 14, which are parallel to each other and arranged at intervals. One end of the reinforcing rib 14 is connected to one side of the fixing plate 13 away from the connection end 411, and the other end of the reinforcing rib 14 is connected to the first mounting surface 11. The reinforcing ribs 14 can increase the strength of the mounting bracket 1 and prevent the mounting of the FPC board assembly 4 from being insufficient.

In an embodiment, the busbar assembly 2 includes a negative output busbar 21. As shown in FIG. 5, the negative output busbar 21 includes a bent output end 211 parallel to an axial direction of the cells 3 and configured to connect an adjacent battery module. Illustratively, the bent output end 211 is attached to the mounting bracket 1 and provided with a connection bolt 212, an axial direction of the connection bolt 212 is perpendicular to a side surface of the mounting bracket 1, and the connection bolt 212 is configured to connect the adjacent battery module and screwed to a mounting hole 2111 of the bent output end 211. The bent output end 211 is formed by a sheet metal bending process, and the length of the bent output end 211 extends along the axial direction of the cells 3. Therefore, the bent output end 211 does not increase the length of each of the cells 3 in the horizontal direction, thereby reducing space occupation. When the battery module is connected to the adjacent battery module, the battery module and the adjacent battery module can be tightened by the connection bolt 212 in the horizontal direction, thereby greatly increasing the space utilization rate.

In an embodiment, the plurality of FPC boards 41 include a first FPC board 412 embedded among the plurality of cells 3 and a second FPC board 413 disposed around an outer periphery of the cells 3. The battery module of the present embodiment includes two first FPC boards 412 and one second FPC board 413. The two first FPC boards 412 are penetrated among the plurality of cells 3 to reduce the space occupation and do not block the first mounting surface 11 or the second mounting surface 12, and do not affect a welding connection between each of the cells 3 and the busbar assembly 2, thereby facilitating the integrated feeding.

In an embodiment, the first FPC board 412 includes a bent extension portion capable of attaching a side of the plurality of cells 3. The bent extension portion has a wavy cross section and easily attaches an outer surface of a cylindrical cell 3. The first FPC plate 412 extends in a straight line at both ends of the bent extension portion to facilitate the fixing.

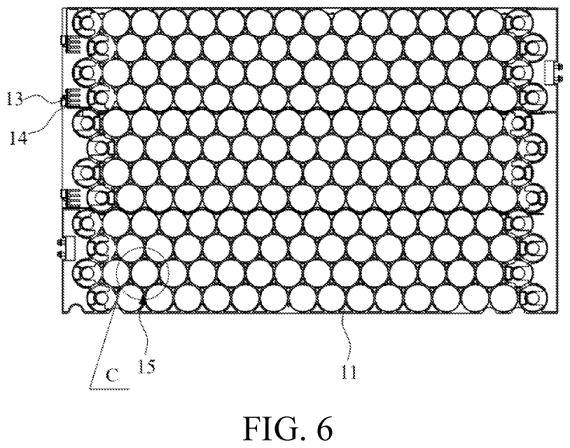

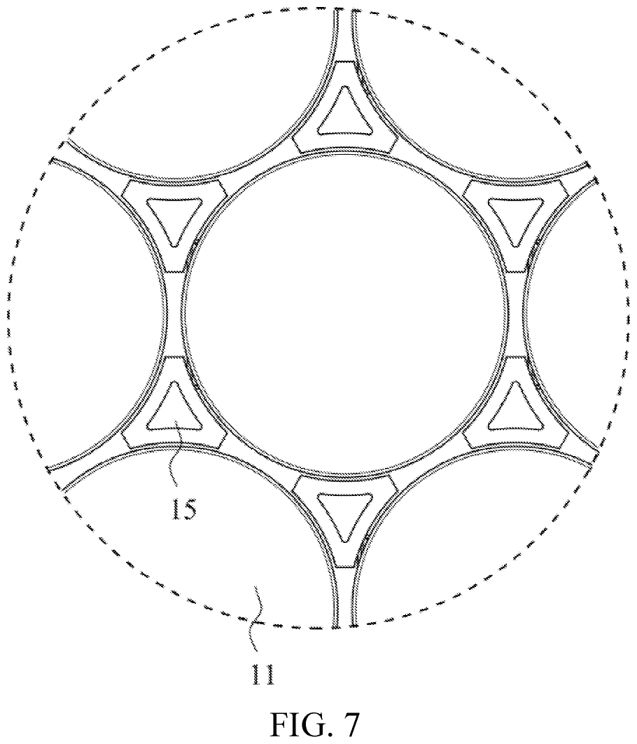

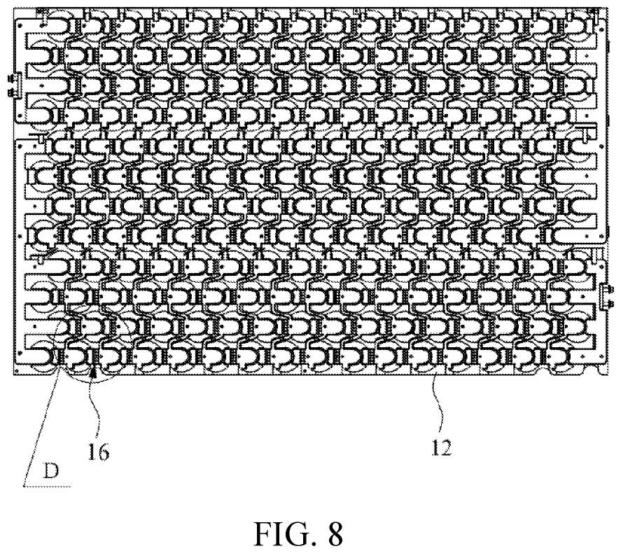

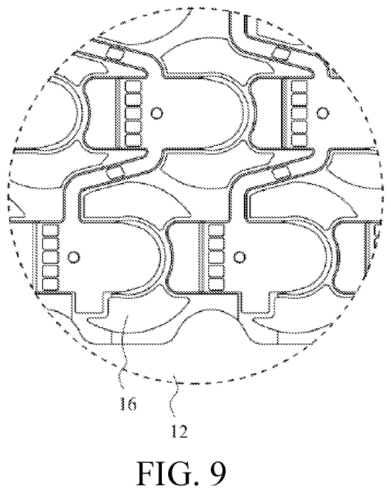

In an embodiment, the mounting bracket 1 includes a plurality of first limiting members 15. As shown in FIGS. 6 and 7, the first limiting members 15 are protruded on the first mounting surface 11 and configured to snap-fit the cells 3. Illustratively, the mounting bracket 1 further includes a plurality of second limiting members 16. As shown in FIGS. 8 and 9, the second limiting members 16 are protruded on the second mounting surface 12 and configured to snap-fit the busbar assembly 2. In the present embodiment, each of the cells 3 is cylindrical in shape, and each of the first limiting members 15 is composed of six protrusions with arc surfaces, where the protrusions are protruded on the first mounting surface 11, and the arc surfaces of the six protrusions are provided concentrically, so that the protrusions can be attached to the cell 3, the positioning accuracy of the cell 3 is increased, and the assembly efficiency of the cell 3 is improved. Each of the second limiting members 16 is designed according to an appearance shape of the bus bar assembly 2 and consists of a plurality of protrusions including curved surfaces and flat surfaces. Of course, in other embodiments, the configuration of the first limiting members 15 and the second limiting members 16 may vary depending on the appearance shapes of the cell 3 and the busbar assembly 2.

1. A battery module, comprising:
a mounting bracket comprising a first mounting surface and a second mounting surface disposed opposite to each other, wherein the first mounting surface is provided with a plurality of fixing plates;
a busbar assembly detachably connected to the mounting bracket and disposed on the second mounting surface;
a plurality of cells arranged on the first mounting surface and connected to the busbar assembly; and
an Flexible Printed Circuit board assembly comprising a plurality of FPC boards and a plurality of connectors, wherein the FPC boards are vertically disposed on the first mounting surface, and a connection end of each of the FPC boards is fixedly connected to respective one of the connectors and riveted to respective one of the fixing plates.

2. The battery module of claim 1, wherein the FPC board assembly further comprises a plurality of reinforcing plates, each of the reinforcing plates is connected to a side of respective one of the connection ends away from respective one of the connectors and riveted to respective one of the fixing plates.

3. The battery module of claim 2, wherein the fixing plate is provided with a plurality of riveting posts, the reinforcing plate and the connection end both are provided with a plurality of positioning holes, and each of the riveting posts is able to pass through respective one of the positioning holes and riveted to the reinforcing plate and the connection end.

4. The battery module of claim 1, wherein the mounting bracket further comprises a plurality of reinforcing ribs connected to a side of the fixing plates away from the connection ends.

5. The battery module of claim 1, wherein the busbar assembly comprises a negative output busbar, and the negative output busbar comprises a bent output end parallel to an axial direction of the cells and configured to connect an adjacent battery module.

6. The battery module of claim 5, wherein the bent output end is attached to the mounting bracket and provided with a connection bolt, an axial direction of the connection bolt is perpendicular to a side surface of the mounting bracket, and the connection bolt is configured to connect the adjacent battery module and screwed to a mounting hole of the bent output end.

7. The battery module of claim 1, wherein the plurality of FPC boards comprise a first FPC board embedded among the plurality of cells and a second FPC board disposed around an outer periphery of the cells.

8. The battery module of claim 7, wherein the first FPC board comprises a bent extension portion capable of attaching a side surface of each of the plurality of cells.

9. The battery module of claim 1, wherein the mounting bracket comprises a plurality of first limiting members protruded on the first mounting surface and configured to snap-fit the cells.

10. The battery module of claim 1, wherein the mounting bracket comprises a plurality of second limiting members protruded on the second mounting surface and configured to snap-fit the busbar assembly.

11. The battery module of claim 2, wherein the mounting bracket comprises a plurality of first limiting members protruded on the first mounting surface and configured to snap-fit the cells.

12. The battery module of claim 2, wherein the mounting bracket comprises a plurality of second limiting members protruded on the second mounting surface and configured to snap-fit the busbar assembly.

13. The battery module of claim 3, wherein the mounting bracket comprises a plurality of first limiting members protruded on the first mounting surface and configured to snap-fit the cells.

14. The battery module of claim 3, wherein the mounting bracket comprises a plurality of second limiting members protruded on the second mounting surface and configured to snap-fit the busbar assembly.

15. The battery module of claim 4, wherein the mounting bracket comprises a plurality of first limiting members protruded on the first mounting surface and configured to snap-fit the cells.

16. The battery module of claim 4, wherein the mounting bracket comprises a plurality of second limiting members protruded on the second mounting surface and configured to snap-fit the busbar assembly.

17. The battery module of claim 5, wherein the mounting bracket comprises a plurality of first limiting members protruded on the first mounting surface and configured to snap-fit the cells.

18. The battery module of claim 5, wherein the mounting bracket comprises a plurality of second limiting members protruded on the second mounting surface and configured to snap-fit the busbar assembly.

19. The battery module of claim 6, wherein the mounting bracket comprises a plurality of first limiting members protruded on the first mounting surface and configured to snap-fit the cells.

20. The battery module of claim 6, wherein the mounting bracket comprises a plurality of second limiting members protruded on the second mounting surface and configured to snap-fit the busbar assembly.
